(19) United States
(12) Patent Application Publication
(10) Pub. No.: US 2009/0224880 A1
(43) Pub. Date: Sep. 10, 2009

(54) Apparatus and Method for Providing an Emergency Alert Function with Adjustable Volume Control

(75) Inventors: Margaret P. Smith, Indianapolis, IN (US); Lisa P. Johnson, Indianapolis, IN (US)

Correspondence Address: Thomson Licensing LLC, P.O. Box 5312, Two Independence Way, PRINCETON, NJ, 08543-5312, US

(73) Assignee: THOMSON LICENSING, Boulogne-Billancourt (FR)

(21) Appl. No.: 11/991,705

(22) PCT Filed: Sep. 9, 2005
(86) PCT No.: PCT/US2005/032380

§ 371 Date: Mar. 7, 2008

(51) Int. Cl. G08B 5/22; H03G 3/00

(52) U.S. Cl. 340/7.5; 381/104

(57) ABSTRACT

An apparatus (20) such as a television signal receiver provides an emergency alert function that enables users to better control the volume level of aural alert outputs. According to an exemplary embodiment, the apparatus (20) includes a tuner (22) operative to tune a channel including a signal indicating an emergency event. A processor (27) is operatively coupled to the tuner (22) and enables an aural output if the signal activates the emergency alert function. The aural output exhibits a user selected volume corresponding to a parameter associated with the emergency alert function.

The present invention generally relates to apparatuses such as television signal receivers, radios or other apparatuses having an emergency alert function, and more particularly, to an apparatus and method for providing an emergency alert function that enables users to control the volume level of an aural alert output based on a parameter associated with the emergency alert function.

Emergency events such as severe weather, natural disasters, fires, civil emergencies, war acts, toxic chemical spills, radiation leaks, or other such conditions can be devastating to unprepared individuals. With weather-related emergencies, authorities such as the National Weather Service (NWS) and the National Oceanographic and Atmospheric Administration (NOAA) are generally able to detect severe weather conditions prior to the general public. Through the use of modern weather detection devices, such as Doppler radar and weather satellites, the NWS and NOAA are able to issue early warnings of severe weather conditions which have saved many lives. However, for such warnings to be effective, they must be communicated to their intended recipients.

Certain apparatuses are capable of receiving emergency alert signals provided by sources such as the NWS and NOAA, and provide an emergency alert function using Specific Area Message Encoding (SAME) technology. Apparatuses using SAME technology typically require a user to perform a setup process for the emergency alert function by selecting items including one or more geographical locations of interest, and one or more types of emergency events which activate the emergency alert function. Once the setup process is complete, the emergency alert function may be activated when incoming emergency alert signals including SAME data indicate the occurrence of an emergency event which corresponds to any of the geographical locations and types of emergency events selected by the user during the setup process. When the emergency alert function is activated, one or more alert outputs such as an audio and/or visual message may be provided to inform individuals of the emergency event.

With conventional apparatuses having an emergency alert function using SAME technology, the volume level at which aural alert outputs are provided may be designated by the user during the setup process. However, this designated volume level is used for all aural alert outputs regardless of when the emergency alert function is activated, or the type of emergency event that causes its activation. This type of volume control for aural alert outputs of the emergency alert function is less than optimal. For example, the user may set the volume to a level that is too low for nighttime hours when the user is sleeping, and/or too loud for daytime hours. Moreover, the use of a single designated volume level may be inappropriate since aural alert outputs for emergency events potentially requiring immediate action (e.g., tornado warning, etc.) are provided at the same level as aural alert outputs for emergency events that may not require immediate action (e.g., thunderstorm advisory, etc.).

Accordingly, there is a need for an apparatus and method for providing an emergency alert function that avoids the foregoing problems, and thereby enables users to better control the volume level of aural alert outputs. The present invention addresses these and/or other issues.

In accordance with an aspect of the present invention, an apparatus having an emergency alert function is disclosed. According to an exemplary embodiment, the apparatus comprises tuning means for tuning a channel including a signal indicating an emergency event. Processing means for enabling an aural output if the signal activates the emergency alert function. The aural output exhibits a user selected volume corresponding to a parameter associated with the emergency alert function.

In accordance with another aspect of the present invention, a method for controlling an apparatus having an emergency alert function is disclosed. According to an exemplary embodiment, the method comprises tuning a channel including a signal indicating an emergency event, enabling an aural output if the signal activates the emergency alert function, and wherein the aural output exhibits a user selected volume corresponding to a parameter associated with the emergency alert function.

In accordance with another aspect of the present invention, a television signal receiver having an emergency alert function is disclosed. According to an exemplary embodiment, the television signal receiver comprises a tuner operative to tune a channel including a signal indicating an emergency event. A processor is operatively coupled to the tuner and enables an aural output if the signal activates the emergency alert function. The aural output exhibits a user selected volume corresponding to a parameter associated with the emergency alert function.

The above-mentioned and other features and advantages of this invention, and the manner of attaining them, will become more apparent and the invention will be better understood by reference to the following description of embodiments of the invention taken in conjunction with the accompanying drawings, wherein:

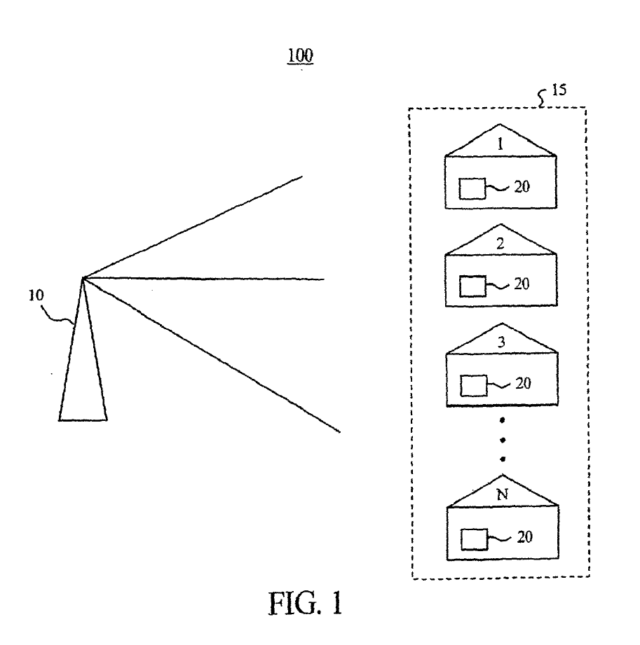

FIG. 1 is an exemplary environment suitable for implementing the present invention;

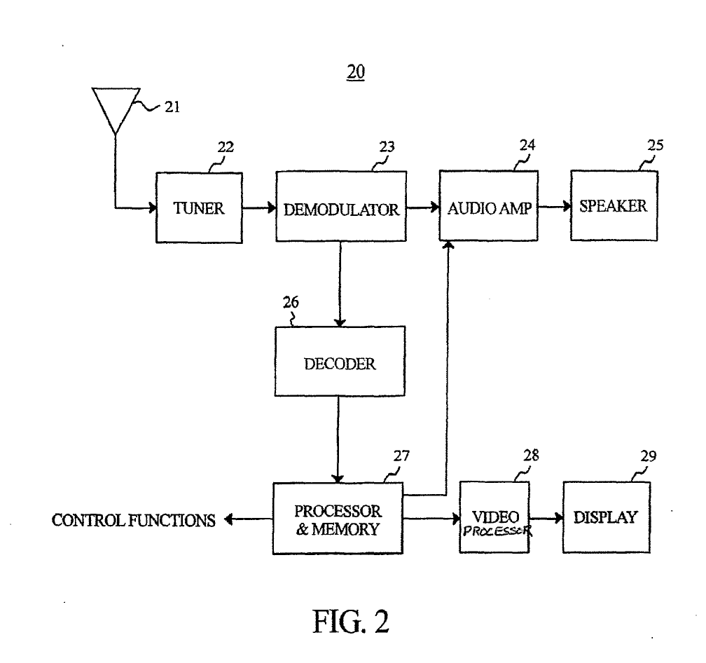

FIG. 2 is a block diagram of an apparatus having an emergency alert function according to an exemplary embodiment of the present invention;

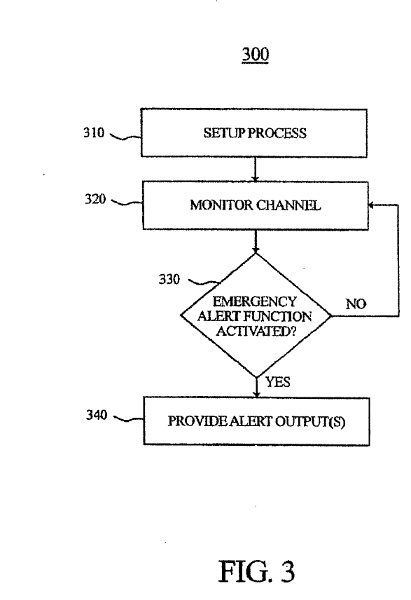

FIG. 3 is a flowchart illustrating exemplary steps for providing an emergency alert function;

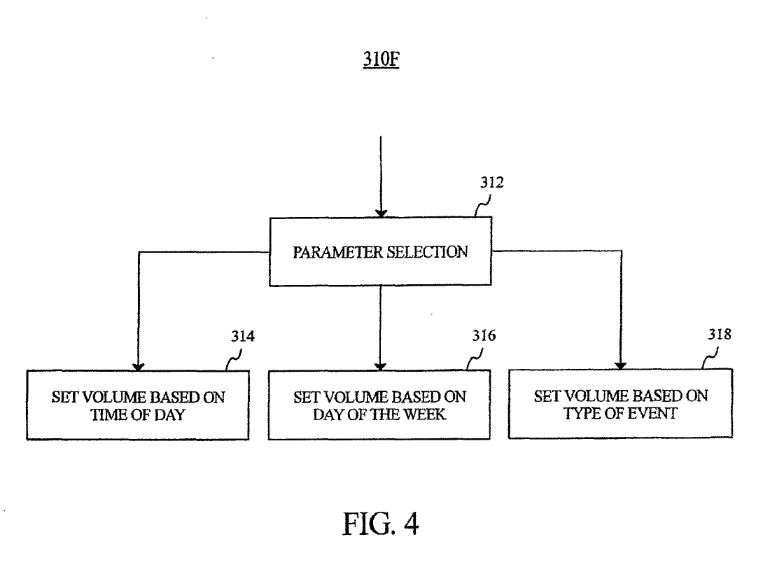

FIG. 4 is a flowchart illustrating steps for selecting the volume of aural alert outputs according to an exemplary embodiment;

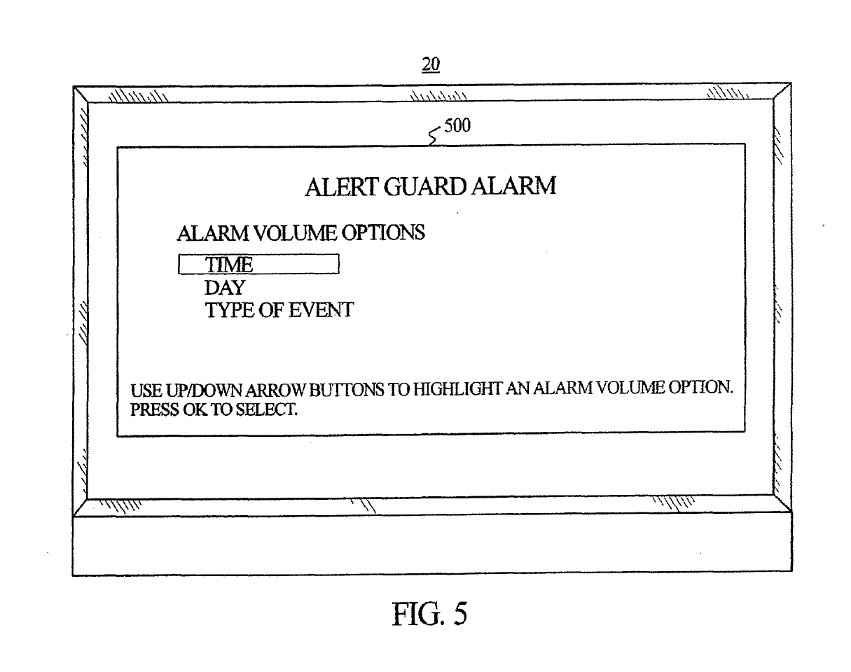

FIG. 5 is an on-screen menu for selecting a parameter for volume control according to an exemplary embodiment of the present invention;

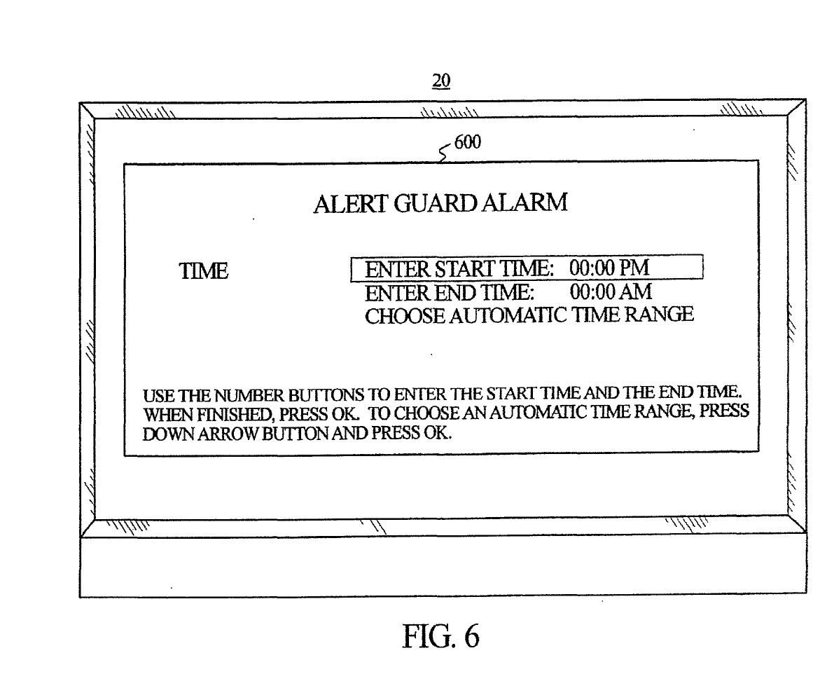

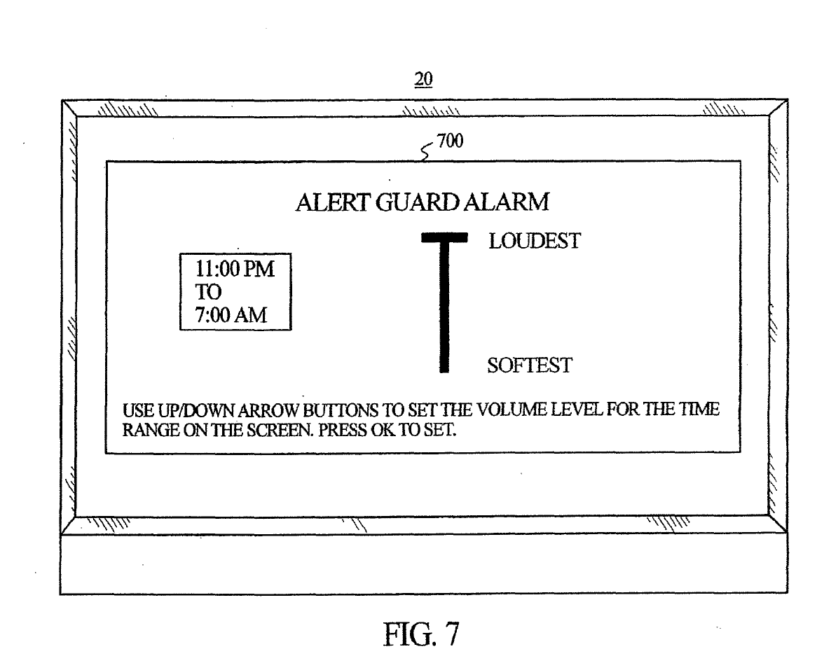

FIGS. 6 and 7 are on-screen menus for controlling volume in accordance with a time of day parameter according to an exemplary embodiment of the present invention;

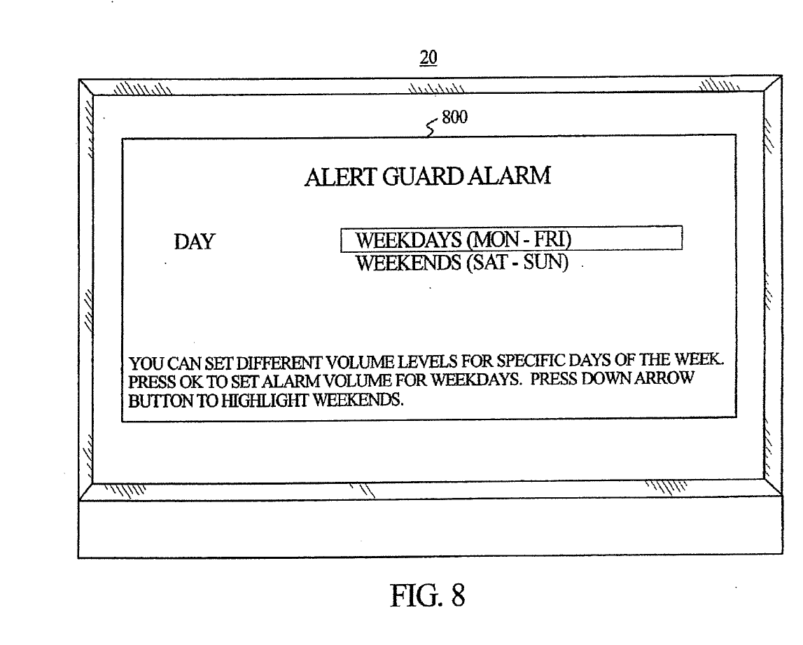

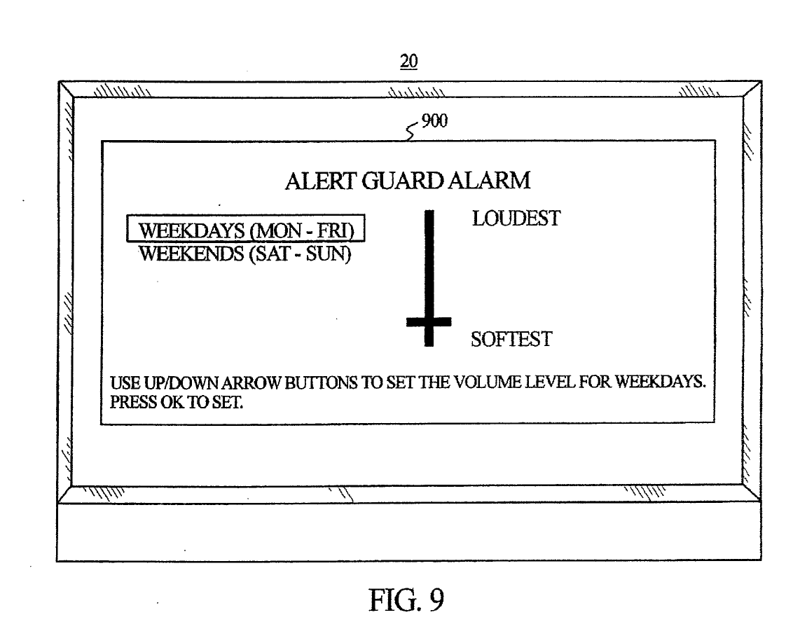

FIGS. 8 and 9 are on-screen menus for controlling volume in accordance with a day of the week parameter according to an exemplary embodiment of the present invention; and

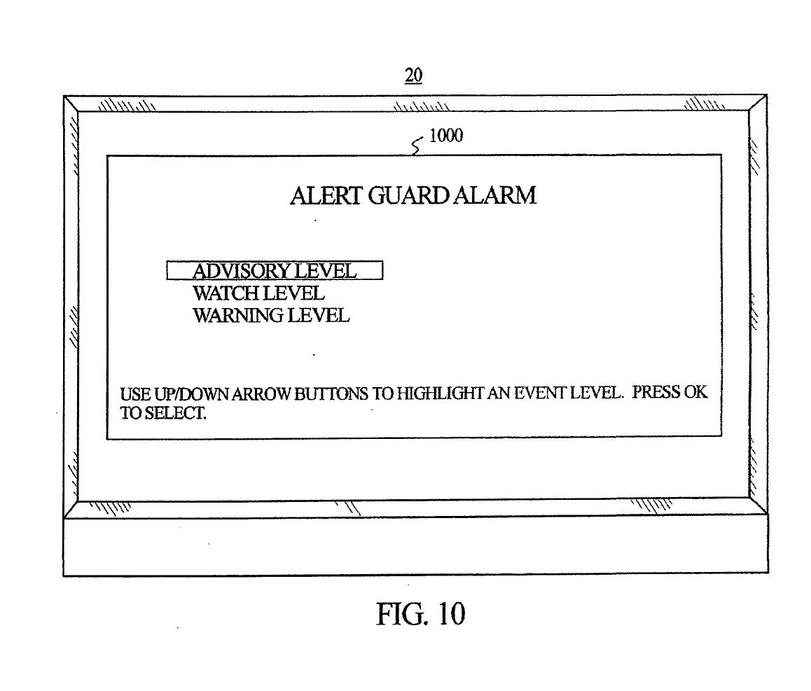

FIGS. 10 to 13 are on-screen menus for controlling volume in accordance with a type of event parameter according to exemplary embodiments of the present invention.

The exemplifications set out herein illustrate preferred embodiments of the invention, and such exemplifications are not to be construed as limiting the scope of the invention in any manner.

Referring now to the drawings, and more particularly to FIG. 1, an exemplary environment 100 suitable for implementing the present invention is shown. In FIG. 1, environment 100 comprises signal transmission means such as one or more signal transmitters 10, dwelling means such as dwelling units 15 (i.e., 1, 2, 3 . . . N, where N may be any positive integer), and signal receiving means such as apparatuses 20.

In FIG. 1, dwelling units 15 may represent residences, businesses and/or other dwelling places located within a particular geographical location, such as but not limited to, a particular continent, country, region, state, area code, zip code, city, county, municipality, subdivision, and/or other definable geographical location. According to an exemplary embodiment, each of the dwelling units 15 is equipped with at least one apparatus 20 having an emergency alert function. Apparatus 20 may be embodied as any type of apparatus having an emergency alert function such as a television signal receiver, radio, or other apparatus. According to the present invention, the emergency alert function enables, among other things, apparatus 20 to receive emergency alert signals and provide one or more alert outputs to notify individuals of an emergency event.

According to an exemplary embodiment, signal transmitter(s) 10 transmit signals including audio, video and/or emergency alert signals which may be received by each apparatus 20. Each of the one or more signal transmitters 10 broadcasts such signals to only a limited range of geographical locations. According to an exemplary embodiment, the emergency alert signals may be provided from an authority such as the NWS, or other authorities such as governmental entities or the like. Signal transmitter(s) 10 may transmit the emergency alert signals in their original form as provided by the authority, or may append digital data representative of the emergency alert signals to other data, or may modify the emergency alert signals in some manner appropriate for its specific transmission format needs. In response to the emergency alert signals, each apparatus 20 may provide one or more alert outputs to thereby notify individuals of the emergency event. Signal transmitter(s) 10 may transmit signals to apparatuses 20 via any wired and/or wireless link such as, but not limited to, terrestrial, cable, satellite, fiber optic, digital subscriber line (DSL), and/or any other type of broadcast and/or multicast means.

Referring to FIG. 2, a block diagram of an exemplary embodiment of apparatus 20 of FIG. 1 is shown. In FIG. 2, apparatus 20 comprises signal receiving means such as signal receiving element 21, tuning means such as tuner 22, demodulation means such as demodulator 23, audio amplification means such as audio amplifier 24, audio output means such as speaker 25, decoding means such as decoder 26, processing means and memory means such as processor and memory 27, video processing means such as video processor 28, and visual output means such as display 29. The audio output means such as speaker 25 and/or the visual output means such as display 29 may be provided external to apparatus 20. Some of the foregoing elements may for example be embodied using integrated circuits (ICs). For clarity of description, certain conventional elements associated with apparatus 20 such as certain control signals, power signals and/or other elements may not be shown in FIG. 2.

Signal receiving element 21 is operative to receive signals including audio, video and/or emergency alert signals from signal sources, such as signal transmitter(s) 10 in FIG. 1. According to an exemplary embodiment, received audio signals may include digitally encoded emergency alert signals. According to another exemplary embodiment, emergency alert signals may be received as separate data packets in a digital transmission system. Signal receiving element 21 may be embodied as any signal receiving element such as an antenna, input terminal or other element.

Tuner 22 is operative to tune channels that provide signals including audio, video and/or emergency alert signals. According to an exemplary embodiment, tuner 22 is capable of tuning channels corresponding to at least the following designated NWS frequencies: 162.400 MHz, 162.425 MHz, 162.450 MHz, 162.475 MHz, 162.500 MHz, 162.525 MHz and 162.550 MHz. Such channels may provide audio signals that include digitally encoded emergency alert signals. Tuner 22 may also tune other frequency channels including those used in terrestrial, cable, satellite and/or other transmissions.

Demodulator 23 is operative to demodulate signals provided from tuner 22, and may demodulate signals in analog and/or digital transmission formats. According to an exemplary embodiment, demodulator 23 demodulates audio signals to thereby generate demodulated audio signals representing audio content such as an NWS audio message, a warning alert tone and/or other audio content. Audio amplifier 24 is operative to amplify the audio signals output from demodulator 23 responsive to one or more control signals provided from processor 27. Speaker 25 is operative to aurally output the amplified audio signals provided from audio amplifier 24.

Decoder 26 is operative to decode signals including audio, video and/or emergency alert signals. According to an exemplary embodiment, decoder 26 decodes audio signals to thereby extract digitally encoded frequency shift keyed (FSK) signals, which represent emergency alert signals indicating an emergency event. Decoder 26 may also perform other decoding functions, such as decoding data which represents emergency alert signals included in the vertical blanking interval (VBI) of an analog television signal.

According to an exemplary embodiment, the emergency alert signals include data comprising SAME data associated with the emergency event. SAME data comprises a digital code representing information such as the specific geographical location affected by the emergency event, the type of emergency event (e.g., tornado watch, radiological hazard warning, civil emergency, etc.), and the expiration time of the event alert. SAME data is used by the NWS and other authorities to improve the specificity of emergency alerts and to decrease the frequency of false alerts. Other data and information may also be included in the emergency alert signals according to the present invention.

Processor and memory 27 are operative to perform various processing and data storage functions of apparatus 20. According to an exemplary embodiment, processor 27 receives the emergency alert signals from decoder 26 and determines whether the emergency alert function of apparatus 20 is activated based on data included in the emergency alert signals. According to this exemplary embodiment, processor 27 compares data in the emergency alert signals to user setup data stored in memory 27 to determine whether the emergency alert function is activated. As will be described later herein, a setup process for the emergency alert function of apparatus 20 allows a user to select items such as an applicable geographical location(s), and type(s) of emergency events (e.g., tornado watch, radiological hazard warning, civil emergency, etc.) which activate the emergency alert function.

When the emergency alert function of apparatus 20 is activated, processor 27 outputs one or more control signals which enable various operations. According to an exemplary embodiment, such control signals enable one or more alert outputs (e.g., aural and/or visual) to thereby notify individuals of the emergency event. Such control signals may also enable other operations of apparatus 20, such as causing it to be switched from an off/standby mode to an on mode. As will be described later herein, the volume of aural alert outputs are based on a parameter associated with the emergency alert function. This parameter may include a time of day the emergency alert function is activated, a day of the week the emergency alert function is activated, or a type of emergency event that activates the emergency alert function. Further details regarding the aforementioned aspects of the present invention will be provided later herein. Memory 27 is operative to store data including user setup data and on-screen menu data for the emergency alert function.

Video processor 28 is operative to process signals including video signals. According to an exemplary embodiment, such video signals may include embedded messages such as NWS text messages and/or other messages that provide details regarding emergency events. Video processor 28 may include closed caption circuitry which enables closed caption displays.

Display 29 is operative to provide visual displays. According to an exemplary embodiment, display 29 may provide visual displays including the aforementioned messages that provide details regarding emergency events. Display 29 may also include a viewable display panel having one or more indicator elements such as light emitting diodes (LEDs), liquid crystal display (LCD) elements, liquid quartz display (LQD) elements, and/or other elements. Such indicator elements may include highlighted indicators, such as monochrome and/or colored indicators, plasma display indicators, and/or conventional lights used as consumer electronic product indicators, and may for example reside apart from apparatus 20, such as on a portable (e.g., non-tethered) lighted panel designed for a wall and/or desk display.

Turning now to FIG. 3, a flowchart 300 illustrating exemplary steps for providing an emergency alert function is shown. For purposes of example and explanation, the steps of FIG. 3 will be described with reference to apparatus 20 of FIG. 2. The steps of FIG. 3 are merely exemplary, and are not intended to limit the present invention in any manner.

At step 310, a setup process for the emergency alert function of apparatus 20 is performed. According to an exemplary embodiment, a user performs this setup process by providing inputs to apparatus 20 (e.g., using a remote control device not shown in FIGS.) responsive to on-screen menus displayed via display 29. According to an exemplary embodiment, the user may select at least the following items during the setup process at step 310:

A. Enable/Disable—The user may select whether to enable or disable the emergency alert function.

B. Monitoring Channel(s)—The user may select one or more channels that are monitored in order to receive emergency alert signals. For example, the user may select channels corresponding to one or more of the following NWS transmission frequencies: 162.400 MHz, 162.425 MHz, 162.450 MHz, 162.475 MHz, 162.500 MHz, 162.525 MHz and 162.550 MHz. Channels may be manually selected by the user, or may be automatically selected by apparatus 20.

C. Geographical Locations—The user may select one or more geographical locations of interest. For example, the user may select a particular continent, country, region, state, area code, zip code, city, county, municipality, subdivision, and/or other definable geographical location. According to an exemplary embodiment, such geographical location(s) may be represented by location codes, such as Federal Information Processing Standard (FIPS) location codes.

D. Event Types—The user may select one or more types of emergency events which activate the emergency alert function. For example, the user may designate that events such as civil emergencies, radiological hazard warnings, and/or tornado warnings activate the emergency alert function, but that events such as a thunderstorm watch do not, etc. The user may also select whether the conventional warning audio tone provided by the NWS and/or other alert mechanism activates the emergency alert function. According to the present invention, different severity or alert levels (e.g., advisory level, watch level, warning level, etc.) may represent different “events.” For example, a thunderstorm watch may be considered a different event from a thunderstorm warning.

E. Alert Outputs—The user may select one or more alert outputs to be provided when the emergency alert function is activated. According to an exemplary embodiment, the user may select visual and/or aural outputs to be provided for each type of emergency event that activates the emergency alert function. For example, the user may select to display a visual message (e.g., an NWS text message as a closed caption display) and/or tune apparatus 20 to a specific channel. The user may also for example select to aurally output a warning tone (e.g., chime, siren, etc.) and/or an audio message (e.g., NWS audio message). Other types of alert outputs may also be provided according to the present invention.

F. Volume Selection—The user may select the volume level at which aural alert outputs (e.g., chime, siren, audio message, etc.) are provided. According to an exemplary embodiment, the user may first select a parameter, such as the time of day, day of the week, or type of emergency event, upon which the volume level of aural alert outputs is based. Alternatively, a default parameter could be automatically used for volume selection, thereby eliminating the need for parameter selection by the user. In either case, the user selects the volume level at which aural alert outputs are provided based on the applicable parameter. In this manner, the volume of aural alert outputs may vary based on the time of day at which the emergency alert function is activated, the day of the week in which the emergency alert function is activated, or the type of emergency event. Further details regarding volume selection according to the present invention will be provided later herein with reference to FIG. 4.

According to the present invention, other menu selections may also be provided at step 310 and/or some of the menu selections described above may be omitted. Data corresponding to the user's selections during the setup process of step 310 is stored in memory 27.

At step 320, apparatus 20 monitors the channel(s) selected by the user during the setup process of step 310 (i.e., item B) for emergency alert signals. According to an exemplary embodiment, tuner 22 monitors the selected channel(s) to thereby receive emergency alert signals. Also according to an exemplary embodiment, apparatus 20 is capable of monitoring a channel and receiving emergency alert signals during all modes of operation, including for example when apparatus 20 is turned on, turned off, and/or during playback of recorded audio and/or video content.

At step 330, a determination is made as to whether the emergency alert function of apparatus 20 is activated. According to an exemplary embodiment, processor 27 makes this determination by comparing data included in the incoming emergency alert signals to data stored in memory 27. As previously indicated herein, the emergency alert signals may include data such as SAME data which represents information including the specific geographical location(s) affected by the emergency event, and the type of emergency event (e.g., tornado watch, radiological hazard warning, civil emergency, etc.). According to an exemplary embodiment, processor 27 compares this SAME data to corresponding user setup data (i.e., items C and D of step 310) stored in memory 27 to thereby determine whether the emergency alert function is activated. In this manner, the emergency alert function of apparatus 20 is activated when the emergency event indicated by the emergency alert signals corresponds to: (1) any geographical location(s) selected by the user under item C of step 310 and (2) any event type(s) selected by the user under item D of step 310.

If the determination at step 330 is negative, process flow loops back to step 320 where tuner 22 continues to monitor the selected channel(s) for emergency alert signals. Alternatively, if the determination at step 330 is positive, process flow advances to step 340 where apparatus 20 provides one or more alert outputs to thereby notify individuals of the emergency event.

According to an exemplary embodiment, processor 27 enables the one or more alert outputs at step 340 in accordance with the user's selections during the setup process of step 310 (i.e., item D), and such alert outputs may be aural and/or visual in nature. For example, aural outputs such as a warning tone and/or an NWS audio message may be provided at step 340 via speaker 25, and the volume of such aural outputs may be controlled in accordance with the volume level set by the user during the setup process of step 310 (i.e., item F). Visual outputs may also be provided at step 340 via display 29 to notify individuals of the emergency event. According to an exemplary embodiment, an auxiliary information display such as an NWS text message (e.g., as a closed caption display) and/or a video output from a specific channel may be provided at step 340 via display 29 under the control of processor 27. Other types of aural and/or visual alert outputs than those expressly described herein may also be provided according to the present invention.

Turning now to FIG. 4, a flowchart 310F illustrating steps for selecting the volume of aural alert outputs according to an exemplary embodiment of the present invention is shown. That is, FIG. 4 provides further details regarding item F of step 310 in FIG. 3. For purposes of example and explanation, the steps of FIG. 4 will be described with reference to apparatus 20 of FIG. 2. The steps of FIG. 4 are merely exemplary, and are not intended to limit the present invention in any manner.

At step 312, a parameter selection is made by a user. According to an exemplary embodiment, the user may make the selection at step 312 through an on-screen menu, such as on-screen menu 500 shown in FIG. 5. As indicated in FIG. 5, the user may provide inputs to apparatus 20 (e.g., using a remote control device not shown in FIGS.) to thereby select a parameter upon which the volume level of aural alert outputs is based. According to an exemplary embodiment, the parameter options include the time of day at which the emergency alert function is activated, the day of the week in which the emergency alert function is activated, or the type of emergency event. It is noted that the user selection of a parameter at step 312 may be optionally. For example, higher-end models of apparatus 20 may include the user parameter selection of step 312. Alternatively, lower-end models of apparatus 20 may be pre-programmed to use a particular parameter, thereby eliminating the need for parameter selection by the user at step 312.

If the user selects the time of day parameter at step 312, process flow advances to step 314 where the user sets the volume for aural alert outputs based on the time of day parameter. According to an exemplary embodiment, the user may specifically define particular time ranges, or may select automatic (i.e., pre-selected) time ranges at step 314. According to this exemplary embodiment, the user may select time ranges at step 314 through an on-screen menu, such as on-screen menu 600 shown in FIG. 6. As indicated in FIG. 6, the user may provide inputs to apparatus 20 (e.g., using a remote control device not shown in FIGS.) to thereby specifically define the particular time ranges by entering a start time and an end time for each range. Alternatively, the user may select and/or adjust the automatic (i.e., pre-selected) time ranges through on-screen menu 600 at step 314. In either case, the selected time ranges should collectively represent one complete day.

Additionally, for each time range, the user may provide inputs to apparatus 20 (e.g., using a remote control device not shown in FIGS.) to thereby select a corresponding volume level for aural alert outputs at step 314. FIG. 7 shows an exemplary on-screen menu 700 that may be used to select volume levels for aural alert outputs at step 314. As indicated in FIG. 7, the user may for example set the volume level to its loudest setting for the time range from 11:00 PM to 7:00 AM since he/she may be sleeping during that time. In this manner, if the emergency alert function of apparatus 20 is activated during the time range from 11:00 PM to 7:00 AM, an aural alert output may be provided at the loudest level. Moreover, the user may for example set the volume level to less than the loudest level for all other time ranges since he/she may be awake or away from home during those times.

If the user selects the day of the week parameter at step 312, process flow advances to step 316 where the user sets the volume for aural alert outputs based on the day of the week parameter. According to an exemplary embodiment, the user may provide inputs to apparatus 20 (e.g., using a remote control device not shown in FIGS.) to thereby select different volume levels for weekdays and weekends at step 316. FIG. 8 shows an exemplary on-screen menu 800 that enables the user to select between a weekdays volume setting, and a weekend volume setting at step 316. If, for example, the user selects the weekdays volume setting via on-screen menu 800, he/she may then be presented with another on-screen menu such as on-screen menu 900 of FIG. 9 that enables the user to select a volume level for aural alert outputs occurring when the emergency alert function of apparatus 20 is activated during weekdays. If the user selects the weekend volume setting via on-screen menu 800, a similar on-screen menu (not shown in FIGS.) may be presented to the user for volume selection for aural alert outputs that occur when the emergency alert function of apparatus 20 is activated during weekends. According to another exemplary embodiment, the user may select the volume level on a day-by-day basis at step 316. For example, the user may select one volume level for Monday, another volume level for Tuesday, and so on.

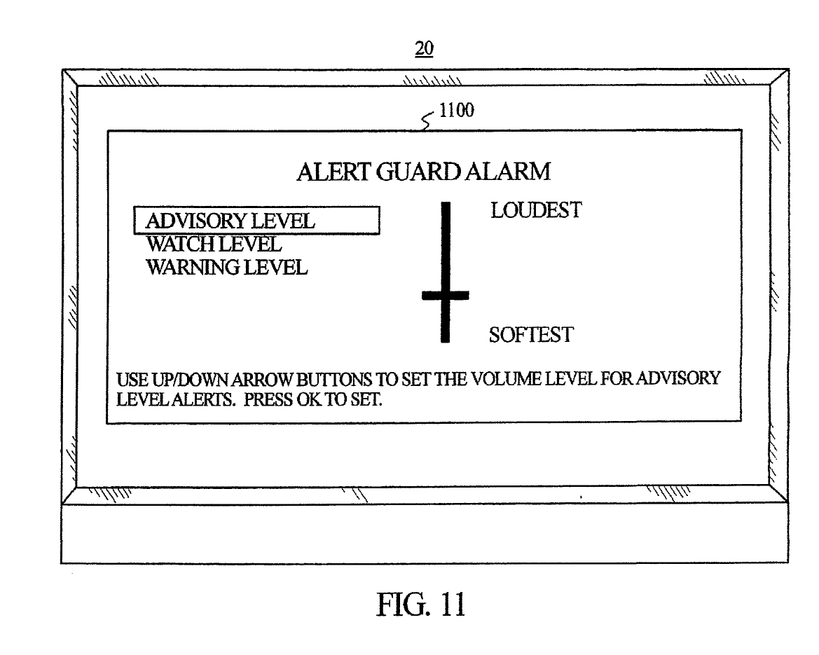

If the user selects the type of event parameter at step 312, process flow advances to step 318 where the user sets the volume for aural alert outputs based on the type of event parameter. According to an exemplary embodiment, the user may provide inputs to apparatus 20 (e.g., using a remote control device not shown in FIGS.) to thereby select the volume level for aural alert outputs at step 318 based on the severity or alert level of the emergency event that activates the emergency alert function of apparatus 20. As previously indicated herein, emergency events may for example represent an advisory level, a watch level, or a warning level. FIG. 10 shows an exemplary on-screen menu 1000 that enables the user to select between an advisory level volume setting, a watch level volume setting, and a warning level volume setting at step 318. If, for example, the user selects the advisory level volume setting via on-screen menu 1000, he/she may then be presented with another on-screen menu such as on-screen menu 1100 of FIG. 11 that enables the user to set the volume level for aural alert outputs occurring as a result of advisory level emergency events activating the emergency alert function. If the user selects the watch level volume setting or the warning level volume setting via on-screen menu 1000, a similar on-screen menu (not shown in FIGS.) may be presented to the user for volume selection for aural alert outputs that occur as a result of emergency events at those respective levels activating the emergency alert function.

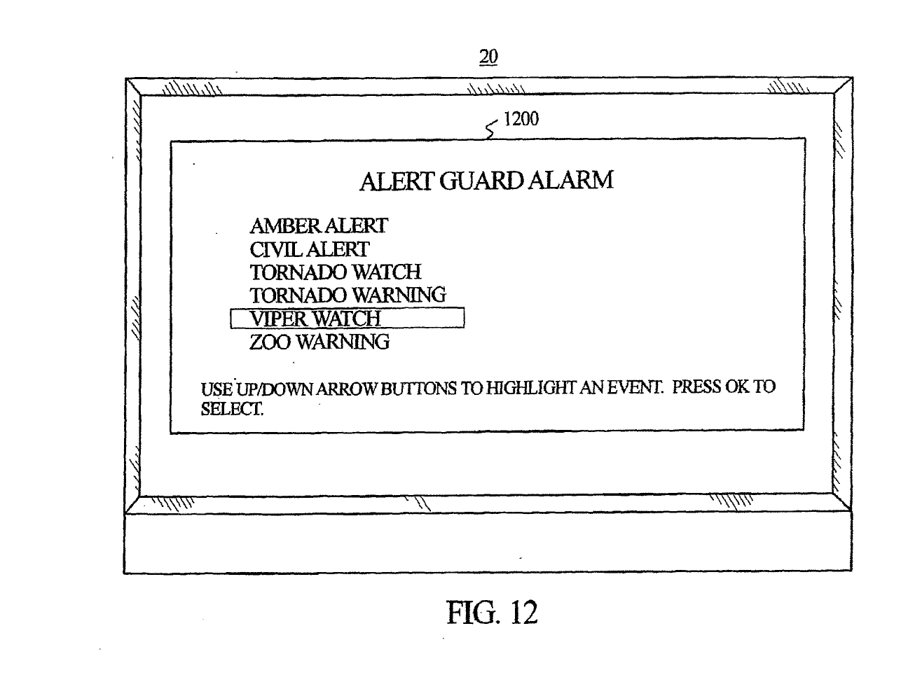

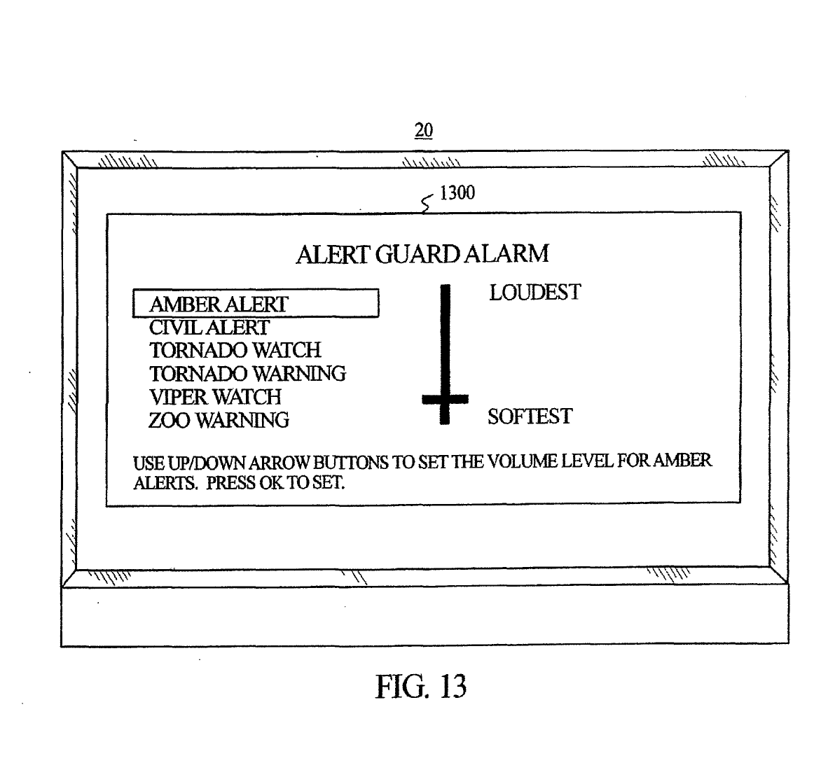

According to another exemplary embodiment, the user may select the volume level for aural alert outputs at step 318 on an event-by-event basis. For example, the user may select aural alert outputs for amber alerts to be provided at one volume level, and aural alert outputs for tornado warnings to be provided at another volume level. FIG. 12 shows an exemplary on-screen menu 1200 that enables the user to select between different emergency events for purposes of volume control. In FIG. 12, it is assumed that all of the emergency events shown in on-screen menu 12 have been previously selected by the user under item D of step 310 as emergency events which activate the emergency alert function of apparatus 20. If, for example, the user selects the amber alert option via on-screen menu 1200, he/she may then be presented with another on-screen menu such as on-screen menu 1300 of FIG. 13 that enables the user to set the volume level for aural alert outputs occurring as a result of amber alerts. Similarly, if the user selects another emergency event via on-screen menu 1200, another on-screen menu (not shown in FIGS.) may be presented to the user for volume selection for aural alert outputs that occur as a result of that emergency event. Other parameters than those expressly described herein may also be used for controlling the volume level of aural alert outputs according to principles of the present invention.

As described herein, the present invention provides an apparatus and method for providing an emergency alert function that enables users to control the volume level of an aural alert output based on a parameter associated with the emergency alert function. The present invention may be applicable to various apparatuses, either with or without an integrated display device and/or a built-in speaker. Accordingly, the phrase “television signal receiver” as used herein may refer to systems or apparatuses including, but not limited to, television sets, computers or monitors that include an integrated display device, and systems or apparatuses such as set-top boxes, video cassette recorders (VCRs), digital versatile disk (DVD) players, video game boxes, personal video recorders (PVRs), computers or other apparatuses that may not include an integrated display device and/or a built-in speaker.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1. An apparatus having an emergency alert function, comprising:
tuning means for tuning a channel including a signal indicating an emergency event;
enabling means for enabling a user to select a parameter from a plurality of parameters, wherein each said parameter provides a different basis for volume control of aural outputs related to said emergency alert function; and
said enabling means enabling an aural output if said signal activates said emergency alert function, wherein said aural output exhibits a volume corresponding to said selected parameter.

2. The apparatus of claim 1, wherein said signal activates said emergency alert function if said emergency event corresponds to a user selected geographical area and a user selected event type.

3. The apparatus of claim 1, wherein said processing means further enables said user to perform a volume setting process for said selected parameter and said aural output exhibits a volume selected during said volume setting process.

4. The apparatus of claim 1, wherein said parameters include:
a time of day said emergency alert function is activated;
a day of the week said emergency alert function is activated; and
a type of said emergency event that activates said emergency alert function.

5. The apparatus of claim 4, wherein said emergency event represents one of:
an advisory level;
a watch level; and
a warning level.

6. A method for controlling an apparatus having an emergency alert function, comprising:
enabling a user to select a parameter from a plurality of parameters, wherein each said parameter provides a different basis for volume control of aural outputs related to said emergency alert function;
tuning a channel including a signal indicating an emergency event; and
enabling an aural output if said signal activates said emergency alert function, wherein said aural output exhibits a volume corresponding to said selected parameter.

7. The method of claim 6, wherein said signal activates said emergency alert function if said emergency event corresponds to a user selected geographical area and a user selected event type.

8. The method of claim 6, further comprised of enabling said user to perform a volume setting process for said selected parameter, and wherein said aural output exhibits a volume selected during said volume setting process.

9. The method of claim 6, wherein said parameters include:
a time of day said emergency alert function is activated;
a day of the week said emergency alert function is activated; and
a type of said emergency event that activates said emergency alert function.

10. The method of claim 9, wherein said emergency event represents one of:
an advisory level;
a watch level; and
a warning level.

11. A television signal receiver having an emergency alert function, comprising:
a tuner operative to tune a channel including a signal indicating an emergency event;
a processor operatively coupled to said tuner for enabling a user to select a parameter from a plurality of parameters, wherein each said parameter provides a different basis for volume control of aural outputs related to said emergency alert function; and
said processor enabling an aural output if said signal activates said emergency alert function, wherein said aural output exhibits a volume corresponding to said selected parameter.

12. The television signal receiver of claim 11, wherein said signal activates said emergency alert function if said emergency event corresponds to a user selected geographical area and a user selected event type.

13. The television signal receiver of claim 11, wherein said processor further enables said user to perform a volume setting process for said selected parameter and said aural output exhibits a volume selected during said volume setting process.

14. The television signal receiver of claim 11, wherein said parameters include:
a time of day said emergency alert function is activated;
a day of the week said emergency alert function is activated; and
a type of said emergency event that activates said emergency alert function.

15. The television signal receiver of claim 14, wherein said emergency event represents one of:
an advisory level;
a watch level; and
a warning level.
